(19) United States
(12) Patent Application Publication
(10) Pub. No.: US 2026/0308839 A1
(43) Pub. Date: Oct. 8, 2026

(54) ORGANIC FIBER FABRIC AND USES OF THE SAME

(71) Applicant: TAIWAN UNION TECHNOLOGY CORPORATION, ZHUBEI CITY (TW)

(72) Inventors: Shur-Fen LIU, ZHUBEI CITY (TW); Jui-Hsiang TANG, ZHUBEI CITY (TW)

(21) Appl. No.: 19/317,775

(22) Filed: Sep. 3, 2025

(30) Foreign Application Priority Data
Apr. 8, 2025 (TW) 114113274

(51) Int. Cl. D06M 10/02; B32B 15/14; B32B 15/20; B32B 38/00; D06M 101/22; D06M 101/32; H05K 1/03

(52) U.S. Cl. CPC D06M 10/025; B32B 15/14; B32B 15/20; B32B 38/0008; H05K 1/0366; B32B 2250/02; B32B 2255/02; B32B 2255/26; B32B 2260/021; B32B 2260/046; B32B 2262/0253; B32B 2262/0284; B32B 2305/076; B32B 2305/18; B32B 2305/55; B32B 2310/14; B32B 2457/08; D06M 2101/22; D06M 2101/32; D10B 2321/042; D10B 2331/04; D10B 2331/14; H05K 2201/0141; H05K 2201/0145; H05K 2201/015; H05K 2201/0154; H05K 2201/0278

(57) ABSTRACT

An organic fiber fabric is provided. The organic fiber fabric comprises polymer fibers. When the organic fiber fabric is measured by X-ray photoelectron spectroscopy (XPS), it has a C 1s (C—N) content ranging from 1 atom % to 21 atom % and a C 1s (O—C═O) content ranging from 1 atom % to 14 atom %. The organic fiber fabric has a surface energy ranging from 50 dyn/cm to 60 dyn/cm. In the XPS analysis, an X-ray wavelength is 400 μm, an X-ray incident angle is 90°, and a scanning time is 15 minutes.

### CLAIM FOR PRIORITY

This application claims the benefit of Taiwan Patent Application No. 114113274 filed on Apr. 8, 2025, the subject matters of which are incorporated herein in their entirety by reference.

### BACKGROUND OF THE INVENTION

### Field of the Invention

The present invention provides an organic fiber fabric, especially an organic fiber fabric having specific X-ray photoelectron spectroscopy properties and surface energy. The present invention also provides a prepreg, a metal-clad laminate and a printed circuit board prepared using the organic fiber fabric.

### Descriptions of the Related Art

Printed circuit boards (PCBs) are substrates of electronic devices for carrying multiple electronic members that are electrically connected with each other to provide a stable circuit working environment. A printed circuit board is manufactured from a metal-clad laminate which is formed of alternatively laminated dielectric layers and conductive layers. Generally, the printed circuit board can be prepared by the following method.

First, a reinforcing material (e.g., a glass-fiber fabric) is impregnated into a resin (e.g., an epoxy resin). The resin-impregnated reinforcing material is then cured to a semi-cured state (known as B-stage) to obtain a prepreg. Afterwards, a predetermined number of prepregs are superimposed to provide a dielectric layer. A conductive layer (e.g., a metal foil) is superimposed on at least one external surface of the dielectric layer to provide a superimposed object. Then, the superimposed object is subjected to a hot-pressing operation (known as C-stage) to obtain a laminate. The conductive layer at the surface of the laminate is etched to form a predetermined circuit pattern. Finally, the etched laminate is subjected to a drilling process to form a plurality of holes thereon, and a conductive material is plated on such holes to form via holes, thereby obtaining the printed circuit board.

In the case when an inorganic glass-fiber fabric is used as the reinforcing material, due to the inorganic glass-fiber fabric having a poor Young's modulus, the printed circuit board manufactured therefrom is susceptible to deformation, resulting in the failure of electronic elements to maintain a good connection with a substrate. In the case when an organic polymer woven fabric is used as the reinforcing material, during an impregnation process, a resin cannot effectively fill each of the pores of the organic polymer woven fabric since the surface tension of the resin does not match that of the organic polymer woven fabric. Consequently, after baking, pores appear on the resultant semi-cured surface, indicating problems such as poor resin impregnation, prepreg debonding, and the like, which have an adverse effect on the performance of the manufactured printed circuit board.

CN 116638836 A discloses a preparation method of a liquid crystal fiber fabric-reinforced laminated board, wherein a liquid crystal fiber fabric is treated with plasma and then immersed in a mixed solution of polydiene, an adhesive and a solvent to obtain a modified liquid crystal fiber fabric. CN 116039186 A discloses a preparation method of a liquid crystal polymer fiber woven fabric-based low-dielectric composite board, wherein the composite board is prepared from a liquid crystal polymer fiber woven fabric and a fluorocarbon resin, and the liquid crystal polymer fiber woven fabric is subjected to a plasma surface treatment. TW I798323 B discloses surface-modified wholly aromatic polyester fibers, in which the ratio of the number of oxygen atoms to the number of carbon atoms on the fiber surface is 30% to 60%. The method to perform surface modification, as taught by TW 1798323 B, comprises using active oxygen-containing substances to act on wholly aromatic polyester polymer-containing wholly aromatic polyester fibers.

However, a metal-clad laminate produced based on prior art still cannot simultaneously have the advantages of a low coefficient of thermal expansion (CTE), good anti-aging performance, good heat resistance after moisture absorption, and a low water absorption rate. Therefore, it is still desirable to provide an electronic material which has all the above advantages simultaneously.

### SUMMARY OF THE INVENTION

In view of the above technical problems, the present invention provides an organic fiber fabric having specific X-ray photoelectron spectroscopy (XPS) properties and surface energy. It has been found that, by controlling relevant XPS properties and surface energy of an organic fiber fabric within specific ranges, a metal-clad laminate prepared using the organic fiber fabric as a reinforcing material can simultaneously have good heat resistance after moisture absorption (expressed by impregnation property), a low water absorption rate, a low dimensional change rate (i.e., coefficient of thermal expansion (CTE)), and good anti-aging performance (expressed by ΔDf).

Therefore, an objective of the present invention is to provide an organic fiber fabric, which comprises polymer fibers, wherein, as measured by XPS, the organic fiber fabric has a C 1s (C—N) content ranging from 1 atom % to 21 atom % and a C 1s (O—C═O) content ranging from 1 atom % to 14 atom %, and has a surface energy ranging from 50 dyn/cm to 60 dyn/cm; wherein the XPS measurement is conducted under the following conditions: an X-ray wavelength of 400 μm, an X-ray incident angle of 90°, and a scanning time of 15 minutes.

In one embodiment of the present invention, as measured by the XPS, the organic fiber fabric has a C 1s (C—N) content ranging from 5 atom % to 15 atom % and a C 1s (O—C═O) content ranging from 5 atom % to 10 atom %.

In one embodiment of the present invention, the organic fiber fabric has a surface energy ranging from 52 dyn/cm to 58 dyn/cm.

In one embodiment of the present invention, as measured by the XPS, the organic fiber fabric has a C 1s (C-C, C—H) content ranging from 65 atom % to 98 atom %.

In one embodiment of the present invention, as measured by the XPS, the organic fiber fabric has a C 1s (C—F) content ranging from 49 atom % to 51 atom %. More specifically, as measured by the XPS, the organic fiber fabric has a C 1s (C—F) content ranging from 49 atom % to 51 atom %, a C 1s (C-C, C—H) content ranging from 47 atom % to 49 atom %, a C 1s (C—N) content ranging from 1 atom % to 2 atom % and a C 1s (O—C═O) content ranging from 1 atom % to 2 atom %.

In one embodiment of the present invention, the polymer fibers are selected from the group consisting of polyethylene terephthalate (PET) fibers, polypropylene fibers, polyamide fibers, polyimide fibers, polyethylene fibers, polyethylenimine (PEI) fibers, poly-p-phenylenebenzobisthiazole fibers, polypyridobisimidazole (PIPD) fibers, polybenzothiazole fibers, polytetrafluoroethylene (PTFE) fibers, liquid crystal polymer (LCP) fibers, and combinations thereof. In a preferred embodiment of the present invention, the polymer fibers are LCP fibers, PET fibers, PEI fibers or PTFE fibers.

In one embodiment of the present invention, the surface energy of the organic fiber fabric is measured by Owens-Wendt-Rabel-Kaelble method, using water and diiodomethane as test liquids, with a test liquid drop size of 2 μL.

In one embodiment of the present invention, the organic fiber fabric is modified by a method selected from the group consisting of an atmospheric plasma modification method, a plasma jet deposition method, a dielectric barrier discharge plasma deposition method, a radio frequency-generated plasma deposition method, and combinations thereof.

Another objective of the present invention is to provide a prepreg, which is a reinforcing material impregnated or coated with a thermosetting resin composition, wherein the reinforcing material comprises the aforementioned organic fiber fabric.

In one embodiment of the present invention, the thermosetting resin composition comprises a thermosetting resin selected from the group consisting of an epoxy resin, a thermosetting phenolic resin, a thermosetting benzoxazine resin, a thermosetting polyphenylene ether resin, and combinations thereof.

In one embodiment of the present invention, the thermosetting resin composition further comprises an additive selected from the group consisting of a hardener, a catalyst, a flame retardant, a filler, an elastomer, a dispersant, a toughener, a viscosity modifier, a thixotropic agent, a defoamer, a leveling agent, a surface treatment agent, a stabilizer, an antioxidant and combinations thereof.

Another objective of the present invention is to provide a metal-clad laminate, which is prepared by laminating the aforementioned prepreg and a metal foil.

Another objective of the present invention is to provide a printed circuit board, which is prepared from the aforementioned metal-clad laminate.

To render the above objectives, technical features and advantages of the present invention more apparent, the present invention will be described in detail with reference to some embodiments hereinafter.

### BRIEF DESCRIPTION OF THE DRAWINGS

Not applicable.

### DESCRIPTION OF THE PREFERRED EMBODIMENTS

Hereinafter, some embodiments of the present invention will be described in detail. However, the present invention may be embodied in various embodiments and should not be limited to the embodiments described in the specification.

Unless it is additionally explained, the expressions “a,” “the,” or the like recited in the specification and claims should include both the singular and the plural forms.

Unless it is additionally explained, while describing the components included in the solution, mixture, composition or glue in the specification and claims, the weight of a solvent is not included in calculation.

As used herein, the XPS analysis conditions are as follows: an X-ray wavelength of 400 μm, an X-ray incident angle of 90°, a scanning time of 15 minutes and a flood gun being used to conduct charge compensation.

As used herein, the surface energy of the organic fiber fabric is measured by Owens-Wendt-Rabel-Kaelble method, using water and diiodomethane as test liquids, with a test liquid drop size of 2 μL.

The effect of the present invention over prior art resides in that the inventors have discovered that, by controlling the contents of surface functional groups of an organic fiber fabric, the organic fiber fabric can have specific XPS properties and surface energy within specific ranges; as a result, a metal-clad laminate prepared using the organic fiber fabric as a reinforming material simultaneously has the advantages of good heat resistance after moisture absorption, a low water absorption rate, a low dimensional change rate and good anti-aging performance. Without being limited by theory, it is believed that the effect of the present invention is achieved due to the organic fiber fabric mentioned having improved resin adhesion property and resin filling property.

The organic fiber fabric of the present invention and its related applications are described hereinafter.

### 1. ORGANIC FIBER FABRIC

### 1.1. XPS Properties

XPS refers to a quantitative spectroscopic technique that measures elemental composition and empirical formula thereof, as well as chemical state and electronic state of the elements within a material. XPS uses a beam of X-rays to irradiate a material to measure the kinetic energy and number of electrons released from 1 to 10 nanometers beneath the material's surface.

The organic fiber fabric of the present invention, as measured by the XPS, has a C 1s (C—N) content ranging from 1 atom % to 21 atom % and a C 1s (O—C═O) content ranging from 1 atom % to 14 atom %. This means that, based on all the detected C atoms, 1 atom % to 21 atom % of the C atoms form C—N bonds, and 1 atom % to 14 atom % of the C atoms form O—C═O bonds. For example, when the organic fiber fabric of the present invention is measured by the XPS, the detected C 1s (C—N) may be 1 atom %, 2 atom %, 3 atom %, 4 atom %, 5 atom %, 6 atom %, 7 atom %, 8 atom %, 9 atom %, 10 atom %, 11 atom %, 12 atom %, 13 atom %, 14 atom %, 15 atom %, 16 atom %, 17 atom %, 18 atom %, 19 atom %, 20 atom %, or 21 atom %, or within a range between any two of the values described herein. In addition, when the organic fiber fabric of the present invention is measured by the XPS, the detected C 1s (O—C═O) may be 1 atom %, 2 atom %, 3 atom %, 4 atom %, 5 atom %, 6 atom %, 7 atom %, 8 atom %, 9 atom %, 10 atom %, 11 atom %, 12 atom %, 13 atom %, or 14 atom %, or within a range between any two of the values described herein.

In one embodiment of the present invention, as measured by the XPS, the organic fiber fabric of the present invention has a C 1s (C—N) content ranging from 1 atom % to 21 atom % and a C 1s (O—C═O) content ranging from 1 atom % to 14 atom %, and further has a C 1s (C-C, C—H) content ranging from 65 atom % to 98 atom %. This means that, based on all the detected C atoms, 65 atom % to 98 atom % of the C atoms form C-C bonds or C—H bonds. For example, when the organic fiber fabric of the present invention is measured by the XPS, the detected C 1s (C-C, C—H) may be 65 atom %, 66 atom %, 67 atom %, 68 atom %, 69 atom %, 70 atom %, 71 atom %, 72 atom %, 73 atom %, 74 atom %, 75 atom %, 76 atom %, 77 atom %, 78 atom %, 79 atom %, 80 atom %, 81 atom %, 82 atom %, 83 atom %, 84 atom %, 85 atom %, 86 atom %, 87 atom %, 88 atom %, 89 atom %, 90 atom %, 91 atom %, 92 atom %, 93 atom %, 94 atom %, 95 atom %, 96 atom %, 97 atom %, or 98 atom %, or within a range between any two of the values described herein.

In one embodiment of the present invention, the organic fiber fabric includes F atoms, and as measured by the XPS, the organic fiber fabric has a C 1s (C—N) content ranging from 1 atom % to 21 atom % and a C 1s (O—C═O) content ranging from 1 atom % to 14 atom %, and further has a C 1s (C—F) content ranging from 49 atom % to 51 atom %. Herein, C 1s (C—F) is an abbreviation of C 1s (C—F, C—F2, C—F3), wherein C—F2 refers to a C atom bonded to two F atoms, and C—F3 refers to a C atom bonded to three F atoms. Therefore, a C 1s (C—F) content ranging from 49 atom % to 51 atom % means that, based on all the detected C atoms, 49 atom % to 51 atom % of the C atoms form C—F bonds, C—F2 bonds, or C—F3 bonds. For example, when the organic fiber fabric of the present invention is measured by the XPS, the detected C 1s (C—F) may be 49 atom %, 50 atom %, or 51 atom %, or within a range between any two of the values described herein. Preferably, as measured by the XPS, the organic fiber fabric has a C 1s (C—F) content ranging from 49 atom % to 51 atom %, a C 1s (C-C, C—H) content ranging from 47 atom % to 49 atom %, a C 1s (C—N) content ranging from 1 atom % to 2 atom %, and a C 1s (O—C═O) content ranging from 1 atom % to 2 atom %.

The detailed testing method of XPS is described as follows. First, an organic fiber fabric sized at 1 (one) cm in length and width is prepared as a test sample, and an X-ray photoelectron spectrometer (Model: K-Alpha, available from Thermo Fisher Scientific) is used to conduct analysis. The XPS analysis conditions are as follows: an X-ray wavelength of 400 μm, an X-ray incident angle of 90°, a scanning time of 15 minutes, and a flood gun being used to conduct charge compensation to increase conductivity. For each test sample, three points are randomly selected for XPS analysis to obtain C 1s characteristic peaks thereof, and the values obtained from the three points are averaged to obtain the atom % of each characteristic peak.

### 1.2. Surface Energy

The organic fiber fabric of the present invention has a surface energy ranging from 50 dyn/cm to 60 dyn/cm. For example, the surface energy of the organic fiber fabric of the present invention can be 50 dyn/cm, 51 dyn/cm, 52 dyn/cm, 53 dyn/cm, 54 dyn/cm, 55 dyn/cm, 56 dyn/cm, 57 dyn/cm, 58 dyn/cm, 59 dyn/cm, or 60 dyn/cm, or within a range between any two of the values described herein. It has been found from that when the organic fiber fabric of the present invention possesses the aforementioned XPS properties and the surface energy described herein, a thermosetting resin composition used to form a dielectric material can be fully adhered to the organic fiber fabric, thereby providing the prepared metal-clad laminate with improved heat resistance after moisture absorption, water absorption rate, coefficient of thermal expansion (CTE), and anti-aging performance.

As used herein, the surface energy is measured by the Owens-Wendt-Rabel-Kaelble method, wherein water and diiodomethane are used as test liquids, with a test liquid drop size of 2 μL. The detailed testing method of surface energy is described as follows. First, an organic fiber fabric sized at 10 cm in length and width is prepared as a test sample, and the test sample is placed on a drop shape analyzer (Model: DSA-100, available from KRÜSS). Next, a dropper filled with a test liquid is placed perpendicular to the surface of the test sample, and the test liquid is dropped onto the surface of the test sample, wherein a drop size is 2 μL, and test liquids are water and diiodomethane, respectively. After the shape of the drop no longer changes and remains constant, the left and right contact angles of the drop are measured. Finally, the total surface energy is calculated using contact angles of water and diiodomethane according to the Owens-Wendt-Rabel-Kaelble method.

### 1.3. Polymer Fibers

There is no particular limitation on polymer fibers that can be used to prepare the organic fiber fabric of the present invention, as long as the prepared organic fiber fabric has the desired XPS properties and surface energy. Examples of the polymer fibers include, but are not limited to, PET fibers, polypropylene fibers, polyamide fibers, polyimide fibers, polyethylene fibers, PEI fibers, poly-p-phenylenebenzobisthiazole fibers, PIPD fibers, polybenzothiazole fibers, PTFE fibers, and LCP fibers. Each of the aforementioned polymer fibers can be used alone or in a mixture of two or more. In one embodiment of the present invention, the polymer fibers are LCP fibers, PET fibers, PEI fibers or PTFE fibers.

As used herein, LCP fibers refer to fibers which are obtained from melt spinning of liquid crystal polyester. The liquid crystal polyester is a polyester that exhibits optical anisotropy (liquid crystal property) in the molten phase. The optical anisotropy can be ascertained by, for example, placing a sample on a hot stage, heating it in a nitrogen atmosphere, and observing the transmitted light from the sample. The type of the liquid crystal polyester is not particularly limited. Examples of the liquid crystal polyester include, but are not limited to, a polyester comprising a structural unit selected from the group consisting of a structural unit derived from an aromatic or alicyclic diol, a structural unit derived from an aromatic or alicyclic dicarboxylic acid, a structural unit derived from an aromatic or alicyclic hydroxyl carboxylic acid, a structural unit derived from an aromatic or alicyclic diamine, a structural unit derived from an aromatic or alicyclic hydroxyl amine, a structural unit derived from an aromatic or alicyclic amino carboxylic acid, and a structural unit derived from combinations of the foregoing.

In general, the total fineness of the polymer fibers can be, for example, 10 dtex to 10,000 dtex, preferably 10 dtex to 5,000 dtex, more preferably 50 dtex to 3,000 dtex, particularly preferably 70 dtex to 2,000 dtex. The filament number of the polymer fibers can be, for example, 2 filaments to 500 filaments, preferably 3 filaments to 300 filaments, more preferably 5 filaments to 200 filaments. When the total fineness and the filament number of the polymer fibers are within the aforementioned ranges, the organic fiber fabric prepared therefrom can have further improved mechanical strength.

### 1.4. Preparation of Organic Fiber Fabric

The contents of surface functional groups of organic fiber fabric can be controlled by a modification method so that the organic fiber fabric has specified XPS properties and surface energy. Examples of the modification method include, but are not limited to, an atmospheric plasma modification method, a plasma jet deposition method, a dielectric barrier discharge plasma deposition method, and a radio frequency-generated plasma deposition method. The aforementioned modification methods can be used alone or in combination. By controlling relevant parameters of the modification method, the contents of specific functional groups on the surface of the organic fiber fabric can be increased or decreased, thereby controlling the XPS properties of interest, such as C 1s (C—N), C 1s (O—C═O), and the like, and the surface energy within specified ranges.

In one embodiment of the present invention, an atmospheric plasma modification method is used to provide a modified organic fiber fabric. The atmospheric plasma modification method utilizes a specific plasma frequency to dissociate nitrogen or oxygen in the air to attach polar functional groups onto the surface of the organic fiber fabric, thereby obtaining a modified surface.

The operation and parameters of the atmospheric plasma modification method are described in detail as follows. First, an organic fiber fabric is placed in an atmospheric plasma generator (Model: ATM3, available from Atmospheric Plasma Co., Ltd.) and located below a plasma nozzle. Next, by setting the type of plasma working gas, the flow rate of plasma working gas, the distance between the surface of organic fiber fabric and the plasma nozzle, the number of operations, and the like, according to the type of the organic fiber fabric and the desired modification target, and setting a plasma power to 0.6 kW to 1.2 kW and a scanning speed to 30 cm/s, the organic fiber fabric is subjected to surface modification to obtain a modified organic fiber fabric. Examples of the type of the plasma working gas include, but are not limited to, air, nitrogen, a combination of nitrogen and air, a combination of nitrogen and oxygen, argon, a combination of argon and air, and a combination of argon and oxygen. By controlling conditions such as the type of plasma working gas, the flow rate of plasma working gas, the number of operations, and the like, the related XPS properties and surface energy can be controlled within specified ranges.

The organic fiber fabric of the present invention may comprise the aforementioned polymer fibers, or may be substantially composed of the aforementioned polymer fibers, or may be composed of the aforementioned polymer fibers. The form of the organic fiber fabric of the present invention includes, but is not limited to, woven fabric, non-woven fabric, roving, chopped strand mat, and surfacing mat. The weight per unit area of the organic fiber fabric of the present invention may be 10 g/m² to 500 g/m², preferably 15 g/m² to 200 g/m². The thickness of the organic fiber fabric of the present invention may be 10 μm to 400 μm, preferably 20 μm to 200 μm. The ratio of the major axis to the minor axis (major axis/minor axis) of the fibers in the organic fiber fabric of the present invention may be 1.1 to 3.0, preferably 1.3 to 2.8.

### 2. PREPREG

The organic fiber fabric of the present invention can be used to prepare a prepreg. Therefore, the present invention also provides a prepreg, which is a reinforcing material impregnated or coated with a thermosetting resin composition, wherein the reinforcing material comprises the organic fiber fabric described above.

### 2.1. Thermosetting Resin Composition

Thermosetting resin compositions are used to form dielectric materials (dielectric layers). In addition to containing a thermosetting resin as an essential component, the thermosetting resin composition according to the present invention may optionally include additives to adaptably improve the processability of the resin composition during preparation, or to improve the physicochemical properties of the resulting electronic material.

### 2.1.1. Thermosetting Resin

As used herein, a thermosetting resin refers to a thermosetting component which has reactive functional groups and which is gradually cured after being heated to form a network structure through a crosslinking reaction. The reactive functional groups refer to functional groups capable of conducting a curing reaction with other groups. Examples of the reactive functional groups include, but are not limited to, hydroxyl, carboxyl, alkenyl, and amino. Examples of the thermosetting resin include, but are not limited to, an epoxy resin, a thermosetting phenolic resin, a thermosetting benzoxazine resin, and a thermosetting polyphenylene ether resin. The aforementioned thermosetting resins can either be used alone or in a mixture of two or more. In the appended examples of the present invention, the commercially available TU943S resin composition available from Taiwan Union Technology Co., Ltd. is used, which contains a thermosetting polyphenylene ether resin.

As used herein, a thermosetting polyphenylene ether resin refers to a resin with at least a repeating unit

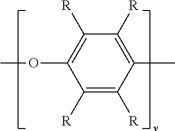

in the main chain and an unsaturated group at the terminal, wherein each R is independently H or a C1-C5 alkyl group, and v is an integer ranging from 1 to 100. The unsaturated group refers to a group capable of undergoing addition polymerization with other components having unsaturated groups, and the addition polymerization can be initiated by light or heat in the presence of a polymerization initiator. Examples of the unsaturated group include, but are not limited to, vinyl, vinylbenzyl, allyl, acrylic, and methacrylic. Examples of the thermosetting polyphenylene ether resin include, but are not limited to, a vinyl-containing polyphenylene ether resin, an allyl-containing polyphenylene ether resin, a vinylbenzyl-containing polyphenylene ether resin, an acrylate-containing polyphenylene ether resin, and a methacrylate-containing polyphenylene ether resin. The aforementioned polyphenylene ether resins may be used alone or in a mixture of two or more.

The method for preparing the thermosetting polyphenylene ether resin is not a key feature of the present invention, and persons having ordinary skill in the art can implement the method based on the present disclosure and their ordinary skill. Therefore, the detailed method for preparing the thermosetting polyphenylene ether resin is not elaborated here. Various methods for preparing the thermosetting polyphenylene ether resin can be found in several references, including U.S. Pat. No. 6,995,195 B2 (vinylbenzyl-containing polyphenylene ether resins), U.S. Pat. No. 5,218,030 A (allyl-containing polyphenylene ether resins), U.S. Pat. No. 5,352,745 A (methacrylate-containing polyphenylene ether resins), U.S. Pat. No. 6,352,782 B2, and US 2016/0280913 A1. These references are incorporated herein in their entirety by reference.

The content of the thermosetting polyphenylene ether resin can be adjusted depending on the need. Generally, based on the total weight of the thermosetting resin composition excluding solvent, the content of the thermosetting polyphenylene ether resin can be 15 wt % to 60 wt %. For example, based on the total weight of the thermosetting resin composition excluding solvent, the content of the thermosetting polyphenylene ether resin can be 15 wt %, 20 wt %, 25 wt %, 30 wt %, 35 wt %, 40 wt %, 45 wt %, 50 wt %, 55 wt %, or 60 wt %, or within a range between any two of the values described herein.

### 2.1.2. Optional Additives

The thermosetting resin composition may further comprise other components as needed, such as additives known in the art, to further improve the physicochemical properties of the obtained prepreg or the metal-clad laminate obtained from the prepreg, or to improve the processability of the thermosetting resin composition during the manufacturing process. Examples of additives that may be added to the thermosetting resin composition include, but are not limited to, a hardener, a catalyst, a flame retardant, a filler, an elastomer, a dispersant, a toughener, a viscosity modifier, a thixotropic agent, a defoamer, a leveling agent, a surface treatment agent, a stabilizer, and an antioxidant. The aforementioned additives can be used alone or in a mixture of two or more. For example, in the appended examples of the present invention, the resin composition TU943S used comprises additives such as a flame retardant, a filler, and an elastomer. The usage and contents of these additives can be adjusted as needed by persons having ordinary skill in the art after reading the disclosure of the subject specification. The following only illustrates the hardener, catalyst, flame retardant, and filler.

### [Hardener]

A hardener refers to a component with unsaturated functional groups that can undergo a crosslinking reaction with other components having unsaturated functional groups (such as an epoxy resin or a thermosetting polyphenylene ether resin) to form a three-dimensional network structure. There is no particular limitation on the type of hardener, as long as it can increase the degree of crosslinking. Examples of the hardener include, but are not limited to, a cyanate ester resin, a benzoxazine resin (BZ resin), a phenolic resin (PN resin), a styrene maleic anhydride copolymer (SMA copolymer), bismaleimide (BMI), dicyandiamide (Dicy), 4,4′-diaminodiphenyl sulfone (DDS), 1,3-divinylbenzene, 1,4-divinylbenzene, trivinylbenzene, 1,3-diisopropenylbenzene, 1,4-diisopropenylbenzene, and a vinyl and/or allyl-containing isocyanurate.

The aforementioned hardeners can be used alone or in a mixture of two or more. The content of the hardener can be adjusted depending on the need. In general, based on the total weight of the thermosetting resin composition excluding solvent, the content of the hardener can be 15 wt % to 60 wt %. For example, based on the total weight of the thermosetting resin composition excluding solvent, the content of the hardener can be 15 wt %, 20 wt %, 25 wt %, 30 wt %, 35 wt %, 40 wt %, 45 wt %, 50 wt %, 55 wt %, or 60 wt %, or within a range between any two of the values described herein.

### [Catalyst]

A catalyst refers to a component that can promote a curing reaction, for example, can promote the ring-opening reaction of epoxy functional groups and reduce the curing reaction temperature of the resin composition. The type of the catalyst is not particularly limited as long as it can promote the curing reaction. Suitable catalysts include, but are not limited to, organic peroxides, tertiary amines, quaternary ammonium salts, imidazole compounds, and pyridine compounds. Examples of the organic peroxide include, but are not limited to, dicumyl peroxide, tert-butyl peroxybenzoate, di-tert-amyl peroxide, isopropylcumyl-tert-butyl peroxide, tert-butylcumylperoxide, di(isopropylcumyl) peroxide, di-tert-butyl peroxide, a, a′-bis(tert-butylperoxy)diisopropyl benzene, benzoyl peroxide, 1,1-bis(tert-butylperoxy)-3,3,5-trimethylcyclohexane, butyl 4,4-di(tert-butylperoxy) valerate, 2,5-dimethyl-2,5-di(tert-butylperoxy) hexane, 2,5-dimethyl-2,5-di(tert-butylperoxy)-3-hexyne. Each of the aforementioned organic peroxides can be used alone or in a mixture of two or more.

The content of the catalyst can be adjusted depending on the need. In general, based on the total weight of the thermosetting resin composition excluding solvent, the content of the catalyst can be 0.1 wt % to 1 wt %. For example, based on the total weight of the thermosetting resin composition excluding solvent, the content of the catalyst can be 0.1 wt %, 0.2 wt %, 0.3 wt %, 0.4 wt %, 0.5 wt %, 0.6 wt %, 0.7 wt %, 0.8 wt %, 0.9 wt %, or 1 wt %, or within a range between any two of the values described herein.

### [Flame Retardant]

A flame retardant can improve the heat resistance and flame retardance of the prepared electronic materials. The types of the flame retardant include, but are not limited to, a phosphorus-containing flame retardant, a bromine-containing flame retardant, a nitrogen-containing compound. Each of the flame retardants can be used alone or in a mixture of two or more.

Examples of the phosphorus-containing flame retardant include, but are not limited to, phosphate esters, phosphazenes, ammonium polyphosphates, metal phosphinates, and melamine phosphate. Examples of the bromine-containing flame retardant include, but are not limited to, tetrabromobisphenol A, decabromodiphenyl oxide, decabrominated diphenyl ethane, 1,2-bis(tribromophenyl) ethane, brominated epoxy oligomer, octabromotrimethylphenyl indane, bis(2,3-dibromopropyl ether), tris(tribromophenyl)triazine, brominated aliphatic hydrocarbon, and brominated aromatic hydrocarbon. Examples of the nitrogen-containing compound include, but are not limited to, melamine and derivatives thereof. The commercially available phosphorus-containing flame retardants include products with the trade name Melapur 200 available from BASF company.

The content of the flame retardant can be adjusted depending on the need, and there is not particular limitation. For example, based on the total weight of the thermosetting resin composition excluding solvent, the content of the flame retardant can be 0 wt % to 30 wt %. For example, based on the total weight of the thermosetting resin composition excluding solvent, the content of the flame retardant can be 0 wt %, 1 wt %, 5 wt %, 10 wt %, 15 wt %, 20 wt %, 25 wt %, or 30 wt %, or within a range between any two of the values described herein.

### [Filler]

A filler can improve mechanical strength, thermal conductivity and dimensional stability of the prepared electronic materials. Examples of the filler include, but are not limited to, those selected from the group consisting of silica (including hollow silica), aluminum oxide, magnesium oxide, magnesium hydroxide, calcium carbonate, talc, clays, aluminum nitride, boron nitride, aluminum hydroxide, silicon aluminum carbide, silicon carbide, sodium carbonate, titanium dioxide, zinc oxide, zirconium oxide, quartzes, diamonds, diamond-like carbon, graphites, calcined kaolin, pryan, micas, hydrotalcite, polytetrafluoroethylene (PTFE) powders, glass beads, ceramic whiskers, carbon nanotubes, and nanosized inorganic powders. Each of the aforementioned fillers can be used alone or in a mixture of two or more.

The content of the filler can be adjusted depending on the need, and there is no particular limitation. For example, based on the total weight of the resin composition excluding solvent, the content of the filler can be 0 wt % to 60 wt %. For example, based on the total weight of the resin composition excluding solvent, the content of the filler can be 0 wt %, 1 wt %, 5 wt %, 10 wt %, 15 wt %, 20 wt %, 25 wt %, 30 wt %, 35 wt %, 40 wt %, 45 wt %, 50 wt %, 55 wt %, or 60 wt %, or within a range between any two of the values described herein.

### 2.1.3. Preparation of Thermosetting Resin Composition

The thermosetting resin composition may be prepared into a varnish for subsequent processing by uniformly mixing the components of the thermosetting resin composition, including the thermosetting resin and other optional components, with a stirrer, and dissolving or dispersing the resultant mixture in a solvent. The solvent can be any inert solvent that can dissolve or disperse the components of the thermosetting resin composition but does not react with the components of the thermosetting resin composition. Examples of the solvent that can dissolve or disperse the components of the thermosetting resin composition include, but are not limited to, toluene, γ-butyrolactone, methyl ethyl ketone, cyclohexanone, butanone, acetone, xylene, methyl isobutyl ketone, N,N-dimethylformamide (DMF), N,N-dimethylacetamide (DMAc), and N-methylpyrolidone (NMP). Each of the mentioned solvents can be used either alone or in any combination. The content of the solvent in the thermosetting resin composition is not particularly limited as long as the components of the thermosetting resin composition can be evenly dissolved or dispersed therein. In the appended examples, methyl ethyl ketone is used as the solvent for the resin composition TU943S.

### 2.2. Preparation of Prepreg

The prepreg of the present invention can be prepared by impregnating or coating the organic fiber fabric of the present invention with the aforementioned thermosetting resin composition. The methods for impregnating or coating include, but are not limited to, dipping, roller coating, die coating, bar coating, gravure coating, spinning coating, slit coating, and spraying. The impregnated or coated organic fiber fabric may be dried at a temperature ranging from 100° C. to 200° C. for 1 (one) minute to 20 minutes to obtain a semi-cured (B-stage) prepreg. In the appended examples, the drying is conducted at 170° C. for 2 minutes to 5 minutes.

### 3. METAL-CLAD LAMINATE AND PRINTED CIRCUIT BOARD

The present invention also provides a metal-clad laminate prepared by laminating the aforementioned prepreg and a metal foil, wherein the prepreg is used as a dielectric layer and the metal foil is used as a conductive layer. In one embodiment of the present invention, the metal-clad laminate of the present invention can be prepared by the following way: superimposing a plurality of the prepregs to form a dielectric layer, then superimposing a metal foil (such as copper foil) as a metal layer on at least one external surface of the dielectric layer to provide a superimposed object comprising the dielectric layer and the metal layer, and performing a hot-pressing operation on the superimposed object to obtain a metal-clad laminate. The hot-pressing operation is performed at a temperature of 180° C. to 240° C. and at a pressure of 20 kg/cm² to 50 kg/cm² (with an initial pressure of 5 kg/cm² to 12 kg/cm²) for 120 minutes to 360 minutes.

The metal-clad laminate of the present invention can be utilized to provide a printed circuit board by further patterning its metal foil. Therefore, the present invention also provides a printed circuit board, which is manufactured by further patterning the metal foil of the metal-clad laminate of the present invention. The method of patterning metal foil is not particularly limited, and examples thereof include, but are not limited to, photolithography.

### 4. EXAMPLES

### 4.1. Testing Methods

The present invention is further illustrated by the specific embodiments hereinafter, wherein the testing instruments and methods used are as follows.

### [XPS Analysis]

First, an organic fiber fabric is cut into a test sample sized at 1 (one) cm in length and width. Next, the test sample is placed in an X-ray photoelectron spectrometer K-Alpha for XPS analysis. The XPS analysis conditions are as follows: an X-ray wavelength of 400 μm, an X-ray incident angle of 90°, a scanning time of 15 minutes, and a flood gun being used to conduct charge compensation to increase conductivity. For each test sample, three points are randomly selected for XPS analysis to obtain each C 1s characteristic peak of the test sample, wherein the values obtained from the three points are averaged to obtain the atom % value of each characteristic peak.

### [Surface Energy Test]

First, an organic fiber fabric is cut into a test sample sized at 10 cm in length and width, and the test sample is placed on a drop shape analyzer DSA-100. Next, a dropper filled with a test liquid is placed perpendicular to the surface of the test sample, and the test liquid is dropped onto the surface of the test sample, wherein a drop size is 2 μL, and water and diiodomethane are used as detection liquids, respectively. After the shape of the drop no longer changes and remains constant, the left and right contact angles of the drop are measured. Finally, the total surface energy is calculated using contact angles of water and diiodomethane according to the Owens-Wendt-Rabel-Kaelble method. The unit of surface energy is dyn/cm.

### [Impregnation Property Test]

A metal-clad laminate for evaluation is etched to remove the metal foil on the external surface thereof to obtain an unclad laminate, which is then cut into a test sample sized at 5 cm in length and width. Next, the test sample is placed in an environmental test oven at 121° C. and 100% relative humidity for 5 hours. Afterwards, the test sample is placed in a tin furnace at 288° C. for 300 seconds. Subsequently, the appearance of the test sample is inspected with unaided eyes to see if there are any popcorns. The evaluation criteria are as follows. If no popcorns are found on the appearance of the test sample, the impregnation property test is considered passed, and the result is recorded as “o”. If any popcorns are found on the appearance of the test sample, the impregnation property test is considered failed, and the result is recorded as “x”.

### [Water Absorption Rate Test]

A metal-clad laminate for evaluation is etched to remove the metal foil on the external surface thereof to obtain an unclad laminate, which is then cut into a test sample sized at 5 cm in length and width. Next, the test sample is baked in an oven at 105° C. for 1 hour, and then the baked test sample is weighed and the obtained weight is designated as W0. Afterwards, the baked test sample is placed in an environmental test oven at a temperature of 121° C. and a relative humidity of 100% for 5 hours, and then the test sample after water absorption is weighed and the obtained weight is designated as W1. The water absorption rate is calculated using the following formula.

$$water absorption rate ( \% ) = \{ \frac{( W 1 - W 0 )}{W 0} \} \times 100 \%$$

### [Dimensional Change Rate Test]

A metal-clad laminate for evaluation is etched to remove the metal foil on the external surface thereof to obtain an unclad laminate, which is then cut into a test sample sized at 5 cm in length and width. Next, a thermal mechanical analyzer (Model: TMA-Q400EM, available from TA Instruments) is used to measure the coefficients of thermal expansion (CTE) of the test sample in the X-axis and Y-axis directions. The measurement method is as follows: the test sample is placed in a heating furnace and the temperature is increased from 50° C. to 125° C. at a rate of 10° C./min, and then the dimensional change rates of the test sample in the X-axis and Y-axis directions are measured using a linear displacement sensor. The unit of dimensional change rate is ppm/° C.

### [Dielectric Dissipation Factor (Df) Measurement]

First, a metal-clad laminate having a length of 24 inches and a width of 18 inches is etched remove the metal foil on the external surface thereof to prepare a test sample. Subsequently, the initial Df of the test sample (hereinafter also referred to as “Df of 0 hour”) is measured and calculated according to IPC-TM-650 2.5.5.13 standard under an operating frequency of 10 GHz.

Next, the test sample is placed in an environmental test oven at a temperature of 85° C. and a relative humidity of 85%. The test sample is taken out from the environmental test oven after 168 hours, 336 hours, 672 hours, 840 hours, and 1008 hours, respectively, and allowed to stand in an environment at a temperature of 25° C. and a relative humidity of 60% for 30 minutes. Afterwards, according to IPC-TM-650 2.5.5.13 standard, under an operating frequency of 10 GHz, the Df of the test sample is measured and calculated, thereby obtaining Df of 168 hours, Df of 336 hours, Df of 672 hours, Df of 840 hours, and Df of 1008 hours.

### 4.2. List of Raw Materials Used in Examples and Comparative Examples

TABLE 1
List of raw materials

| Model | Description |
|---|---|
| HT0021 | LCP fiber fabric, available from Kurary |
| CFJNT002 | PET fiber fabric, available from Tiong |
| | Liong Industrial |
| PEI | PEI fiber fabric, available from Taiwan |
| | Textile Research Institute |
| T010 | PTFE fiber fabric, available from STERN EWS |
| TU943S | Thermosetting resin composition, available |
| | from Taiwan Union Technology Co., Ltd. |
| LH408 | Copper foil (thickness: 18 μm), from |
| | Co-tech Development |

### 4.3. Preparation of Organic Fiber Fabric

First, organic fiber fabrics sized at 30 cm in length and width were prepared, and placed in an atmospheric plasma generator ATM3 and below a plasma nozzle. The types of the organic fiber fabrics are shown in Table 2 below. Next, by setting the type of plasma working gas, the flow rate of plasma working gas, the distance between the surface of organic fiber fabrics and the plasma nozzle and the number of operations according to Table 2 below, and setting a plasma power to 0.6 kW to 1.2 kW and a scanning speed to 30 cm/s, the surfaces of organic fiber fabrics were subjected to a modification treatment to obtain modified organic fiber fabrics of the present invention of Examples 1 to 7 and the comparative organic fiber fabrics of Comparative Examples 5 to 7. Comparative organic fiber fabrics of Comparative Examples 1 to 4 were not modified.

The various properties of the organic fiber fabrics of the present invention of Examples 1 to 7 and the comparative organic fiber fabrics of Comparative Examples 1 to 7, including XPS properties and surface energy, were determined according to the methods described above, and the results are listed in Table 3-1 and Table 3-2.

TABLE 2
Modification conditions of organic fiber fabrics

| | | Organic fiber | | Operation | Flow rate of | Number of |
|---|---|---|---|---|---|---|
| | | fabric | Working gas | distance (mm) | gas (mPa) | operations |
| Example | 1 | HT0021 | Nitrogen | 8 | 0.15 | 2 |
| | 2 | HT0021 | Air | 8 | 0.15 | 3 |
| | 3 | CFJNT002 | Nitrogen | 8 | 0.15 | 2 |
| | 4 | CFJNT002 | Air | 8 | 0.15 | 2 |
| | 5 | PEI | Nitrogen | 8 | 0.15 | 2 |
| | 6 | PEI | Air | 8 | 0.15 | 2 |
| | 7 | T010 | Nitrogen | 5 | 240.00 | 3 |
| Comparative | 1 | HT0021 | N.A. | | | |
| Example | 2 | CFJNT002 | N.A. | | | |
| | 3 | PEI | N.A. | | | |
| | 4 | T010 | N.A. | | | |
| | 5 | HT0021 | Nitrogen | 8 | 0.15 | 3 |
| | 6 | CFJNT002 | Nitrogen | 8 | 0.15 | 3 |
| | 7 | PEI | Nitrogen | 8 | 0.15 | 3 |

N.A.: not applicable

TABLE 3-1
Properties of organic fiber fabrics of Examples 1 to 7

| | Example | | | | | | |
|---|---|---|---|---|---|---|---|
| | 1 | 2 | 3 | 4 | 5 | 6 | 7 |
| C 1s (C—N) | 13.90 | 13.50 | 1.50 | 1.30 | 20.90 | 20.80 | 1.24 |
| (atom %) | | | | | | | |
| C 1s (O—C═O) | 7.20 | 7.10 | 13.30 | 12.50 | 7.40 | 6.90 | 1.03 |
| (atom %) | | | | | | | |
| C 1s (C—C, C—H) | 78.90 | 79.00 | 39.20 | 40.60 | 71.70 | 72.20 | 47.90 |
| (atom %) | | | | | | | |
| C 1s (C—F) | 0 | 0 | 0 | 0 | 0 | 0 | 49.70 |
| (atom %) | | | | | | | |
| Contact angle | 63.6° | 64.3° | 51.6° | 53.1° | 46.2° | 48.3° | 60.2° |
| (water) | | | | | | | |
| Contact angle | 44.0° | 36.9° | 35.8° | 36.2° | 38.5° | 37.2° | 44.0° |
| (diiodomethane) | | | | | | | |
| Surface energy | 52.1 | 51.5 | 55.3 | 56.3 | 58.8 | 57.8 | 54.1 |
| (unit: dyn/cm) | | | | | | | |

TABLE 3-2
Properties of organic fiber fabrics of Comparative Examples 1 to 7

| | Comparative Example | | | | | | |
|---|---|---|---|---|---|---|---|
| | 1 | 2 | 3 | 4 | 5 | 6 | 7 |
| C 1s (C—N) | 13.40 | 0 | 20.50 | 0 | 14.40 | 1.90 | 21.30 |
| (atom %) | | | | | | | |
| C 1s (O—C═O) | 6.50 | 9.90 | 5.90 | 0 | 8.00 | 16.60 | 8.90 |
| (atom %) | | | | | | | |
| C 1s (C—C, C—H) | 80.10 | 43.30 | 73.60 | 49.20 | 77.60 | 35.10 | 69.80 |
| (atom %) | | | | | | | |
| C 1s (C—F) | 0 | 0 | 0 | 50.40 | 0 | 0 | 0 |
| (atom %) | | | | | | | |
| Contact angle | 89.2° | 72.1° | 66.5° | 103.1° | 27.7° | 35.3° | 21.1° |
| (water) | | | | | | | |
| Contact angle | 34.6° | 33.6° | 30.2° | 37.9° | 22.1° | 27.3° | 24.2° |
| (diiodomethane) | | | | | | | |
| Surface energy | 42.9 | 45.8 | 48.9 | 35.6 | 66.2 | 61.9 | 68.0 |
| (unit: dyn/cm) | | | | | | | |

### 4.4. Preparation of Prepreg and Metal-Clad Laminate

The prepregs of Examples 1 to 7 and Comparative Examples 1 to 7 were prepared as follows. First, the organic fiber fabrics of Examples 1 to 7 and Comparative Examples 1 to 7 were respectively impregnated in a thermosetting resin composition (Model: TU943S) by a roll coater, and the thicknesses of the organic fiber fabrics after impregnation were controlled to a proper extent. Next, the impregnated organic fiber fabrics were placed in an oven at 170° C. and heated and baked for 2 minutes to 5 minutes to obtain the prepregs of Examples 1 to 7 and Comparative Examples 1 to 7.

Metal-clad laminates were prepared using the prepregs of Examples 1 to 7 and Comparative Examples 1 to 7, respectively. First, one sheet of copper foil (Model: LH408) was superimposed on one external surface of each of the prepregs to obtain superimposed objects. Next, the superimposed objects were placed in a hot-press machine to be cured through a high temperature hot-pressing to obtain metal-clad laminates of Examples 1 to 7 and Comparative Examples 1 to 7. The hot-pressing conditions were as follows: heating to 200° C. to 220° C. at a heating rate of 3° C./min, and hot-pressing at 200° C. to 220° C. for 240 minutes at a full pressure of 40 kg/cm² (with an initial pressure of 8 kg/cm²).

The properties of the metal-clad laminates of Examples 1 to 7 and Comparative Examples 1 to 7, including impregnation property, water absorption rate, dimensional change rate, Df and ΔDf, were determined according to the aforementioned testing methods, and the results are listed in Tables 4-1 and 4-2.

TABLE 4-1
Properties of the metal-clad laminates of Examples 1 to 7

| | | Example | | | | | | |
|---|---|---|---|---|---|---|---|---|
| | | 1 | 2 | 3 | 4 | 5 | 6 | 7 |
| Impregnation | | ∘ | ∘ | ∘ | ∘ | ∘ | ∘ | ∘ |
| property | | | | | | | | |
| Water absorption rate | | 0.12% | 0.16% | 0.37% | 0.40% | 0.16% | 0.19% | 0.09% |
| X-axis dimensional | | 51 | 52 | 52 | 55 | 55 | 55 | 63 |
| change rate (unit: | | | | | | | | |
| ppm/° C.) | | | | | | | | |
| Y-axis dimensional | | 62 | 67 | 53 | 56 | 56 | 57 | 64 |
| change rate (unit: | | | | | | | | |
| ppm/° C.) | | | | | | | | |
| Df × 10⁻³ | 0 hr. | 0.93 | 0.92 | 2.01 | 1.94 | 1.13 | 1.14 | 0.85 |
| @10 GHz | 168 hrs. | 1.49 | 1.60 | 3.44 | 3.48 | 1.86 | 1.96 | 1.39 |
| | 336 hrs. | 1.39 | 1.67 | 3.53 | 3.56 | 1.94 | 2.01 | 1.48 |
| | 672 hrs. | 1.43 | 1.75 | 3.59 | 3.64 | 2.02 | 2.09 | 1.51 |
| | 840 hrs. | 1.57 | 1.87 | 3.65 | 3.70 | 2.08 | 2.11 | 1.55 |
| | 1008 hrs. | 1.71 | 1.81 | 3.71 | 3.73 | 2.02 | 2.15 | 1.63 |

| | | | | | | | |
|---|---|---|---|---|---|---|---|
| ΔDf × 10⁻³ @10 GHz | 0.78 | 0.89 | 1.70 | 1.79 | 0.89 | 1.01 | 0.78 |

Note:
ΔDf is the difference between Df of 1008 hours and Df of 0 hour

TABLE 4-2
Properties of the metal-clad laminates of Comparative Examples 1 to 7

| | | Comparative Example | | | | | | |
|---|---|---|---|---|---|---|---|---|
| | | 1 | 2 | 3 | 4 | 5 | 6 | 7 |
| Impregnation | | x | x | ∘ | x | ∘ | ∘ | ∘ |
| property | | | | | | | | |
| Water absorption rate | | 0.30% | 0.72% | 0.37% | 0.33% | 0.16% | 0.41% | 0.19% |
| X-axis dimensional | | 70 | 59 | 60 | 72 | 52 | 48 | 52 |
| change rate (unit: | | | | | | | | |
| ppm/° C.) | | | | | | | | |
| Y-axis dimensional | | 64 | 65 | 61 | 70 | 57 | 51 | 53 |
| change rate (unit: | | | | | | | | |
| ppm/° C.) | | | | | | | | |
| Df × 10⁻³ | 0 hr. | 0.96 | 2.00 | 1.43 | 0.87 | 0.89 | 1.96 | 1.14 |
| @10 GHz | 168 hrs. | 1.47 | 4.08 | 2.77 | 1.38 | 1.67 | 3.81 | 2.37 |
| | 336 hrs. | 1.51 | 4.22 | 2.57 | 1.42 | 1.50 | 3.96 | 2.27 |
| | 672 hrs. | 1.56 | 4.36 | 2.81 | 1.50 | 1.56 | 4.08 | 2.47 |
| | 840 hrs. | 1.85 | 4.53 | 2.95 | 1.76 | 1.74 | 4.21 | 2.38 |
| | 1008 hrs. | 1.98 | 4.71 | 3.12 | 1.89 | 1.83 | 4.33 | 2.38 |

| | | | | | | | |
|---|---|---|---|---|---|---|---|
| ΔDf × 10⁻³ @10 GHz | 1.02 | 2.71 | 1.69 | 1.02 | 0.94 | 2.37 | 1.24 |

Note:
ΔDf is the difference between Df of 1008 hours and Df of 0 hour

As shown in Table 4-1, the results of Examples 1 to 7 show that each of the metal-clad laminates produced using the organic fiber fabrics of the present invention simultaneously possesses good heat resistance after moisture absorption (expressed by impregnation property), a low water absorption rate, a low dimensional change rate (i.e., coefficient of thermal expansion (CTE)), and good anti-aging performance (expressed by ΔDf). In particular, Examples 1 to 7 show that even though the organic fiber fabrics used are of different types, as long as the organic fiber fabrics possess both the XPS and surface energy technical characteristics of the present invention, the metal-clad laminates obtained therefrom can simultaneously possess the aforementioned good properties.

By contrast, as shown in Table 4-2, if organic fiber fabrics do not simultaneously possess the XPS and surface energy technical characteristics of the present invention, then no matter what their types are or whether they have been modified or not, the metal-clad laminates produced therefrom cannot simultaneously have the advantages of good heat resistance after moisture absorption, low water absorption rate, low dimensional change rate, and good anti-aging performance. In particular, the comparison of Examples 1 and 2 with Comparative Examples 1 and 5 shows that, under the premise that the organic fiber fabrics possess the XPS technical characteristics of the present invention, when the surface energy values of the organic fiber fabrics are within the specified range of the present invention, the obtained metal-clad laminates can have the best anti-aging performance (lowest ΔDf). The same results can also be seen in the comparison of Examples 3 and 4 with Comparative Examples 2 and 6, and the comparison of Examples 5 and 6 with Comparative Examples 3 and 7.

The above examples are used to illustrate the principle and efficacy of the present invention and show the inventive features thereof, but are not used to limit the scope of the present invention. People skilled in this field may proceed with a variety of modifications and replacements based on the disclosures and suggestions of the invention as described. Therefore, the scope of protection of the present invention is that as defined in the claims as appended.

What is claimed is:

1. An organic fiber fabric, which comprises polymer fibers, wherein, as measured by X-ray photoelectron spectroscopy (XPS), the organic fiber fabric has a C 1s (C—N) content ranging from 1 atom % to 21 atom % and a C 1s (O—C═O) content ranging from 1 atom % to 14 atom %, and has a surface energy ranging from 50 dyn/cm to 60 dyn/cm; wherein the XPS measurement is conducted under the following conditions: an X-ray wavelength of 400 μm, an X-ray incident angle of 90°, and a scanning time of 15 minutes.

2. The organic fiber fabric of claim 1, wherein, as measured by the X-ray photoelectron spectroscopy (XPS), the organic fiber fabric has a C 1s (C—N) content ranging from 5 atom % to 15 atom % and a C 1s (O—C═O) content ranging from 5 atom % to 10 atom %.

3. The organic fiber fabric of claim 1, wherein the organic fiber fabric has a surface energy ranging from 52 dyn/cm to 58 dyn/cm.

4. The organic fiber fabric of claim 1, wherein, as measured by the X-ray photoelectron spectroscopy (XPS), the organic fiber fabric has a C 1s (C-C, C—H) content ranging from 65 atom % to 98 atom %.

5. The organic fiber fabric of claim 1, wherein, as measured by the X-ray photoelectron spectroscopy (XPS), the organic fiber fabric has a C 1s (C—F) content ranging from 49 atom % to 51 atom %.

6. The organic fiber fabric of claim 1, wherein the polymer fibers are selected from the group consisting of polyethylene terephthalate (PET) fibers, polypropylene fibers, polyamide fibers, polyimide fibers, polyethylene fibers, polyethylenimine (PEI) fibers, poly-p-phenylenebenzobisthiazole fibers, polypyridobisimidazole (PIPD) fibers, polybenzothiazole fibers, polytetrafluoroethylene (PTFE) fibers, liquid crystal polymer (LCP) fibers, and combinations thereof.

7. The organic fiber fabric of claim 2, wherein the polymer fibers are selected from the group consisting of polyethylene terephthalate (PET) fibers, polypropylene fibers, polyamide fibers, polyimide fibers, polyethylene fibers, polyethylenimine (PEI) fibers, poly-p-phenylenebenzobisthiazole fibers, polypyridobisimidazole (PIPD) fibers, polybenzothiazole fibers, polytetrafluoroethylene (PTFE) fibers, liquid crystal polymer (LCP) fibers, and combinations thereof.

8. The organic fiber fabric of claim 3, wherein the polymer fibers are selected from the group consisting of polyethylene terephthalate (PET) fibers, polypropylene fibers, polyamide fibers, polyimide fibers, polyethylene fibers, polyethylenimine (PEI) fibers, poly-p-phenylenebenzobisthiazole fibers, polypyridobisimidazole (PIPD) fibers, polybenzothiazole fibers, polytetrafluoroethylene (PTFE) fibers, liquid crystal polymer (LCP) fibers, and combinations thereof.

9. The organic fiber fabric of claim 1, wherein the surface energy of the organic fiber fabric is measured by Owens-Wendt-Rabel-Kaelble method, using water and diiodomethane as test liquids, with a test liquid drop size of 2 μL.

10. The organic fiber fabric of claim 2, wherein the surface energy of the organic fiber fabric is measured by Owens-Wendt-Rabel-Kaelble method, using water and diiodomethane as test liquids, with a test liquid drop size of 2 μL.

11. The organic fiber fabric of claim 3, wherein the surface energy of the organic fiber fabric is measured by Owens-Wendt-Rabel-Kaelble method, using water and diiodomethane as test liquids, with a test liquid drop size of 2 μL.

12. The organic fiber fabric of claim 1, wherein the organic fiber fabric is modified by a method selected from the group consisting of an atmospheric plasma modification method, a plasma jet deposition method, a dielectric barrier discharge plasma deposition method, a radio frequency-generated plasma deposition method, and combinations thereof.

13. The organic fiber fabric of claim 2, wherein the organic fiber fabric is modified by a method selected from the group consisting of an atmospheric plasma modification method, a plasma jet deposition method, a dielectric barrier discharge plasma deposition method, a radio frequency-generated plasma deposition method, and combinations thereof.

14. The organic fiber fabric of claim 3, wherein the organic fiber fabric is modified by a method selected from the group consisting of an atmospheric plasma modification method, a plasma jet deposition method, a dielectric barrier discharge plasma deposition method, a radio frequency-generated plasma deposition method, and combinations thereof.

15. A prepreg, which is a reinforcing material impregnated or coated with a thermosetting resin composition, wherein the reinforcing material comprises the organic fiber fabric of claim 1.

16. The prepreg of claim 15, wherein the thermosetting resin composition comprises a thermosetting resin selected from the group consisting of an epoxy resin, a thermosetting phenolic resin, a thermosetting benzoxazine resin, a thermosetting polyphenylene ether resin, and combinations thereof.

17. A metal-clad laminate, which is prepared by laminating the prepreg of claim 15 and a metal foil.

18. A printed circuit board, which is prepared from the metal-clad laminate of claim 17.
